(19) United States
(12) Patent Application Publication
(10) Pub. No.: US 2018/0230352 A1
(43) Pub. Date: Aug. 16, 2018

(54) THERMALLY CONDUCTIVE RESIN COMPOSITION

(71) Applicant: DENKA COMPANY LIMITED, Tokyo (JP)

(72) Inventor: Go TAKEDA, Tokyo (JP)

(21) Appl. No.: 15/750,369

(22) PCT Filed: Aug. 25, 2016
(86) PCT No.: PCT/JP2016/074859

§ 371 Date: Feb. 5, 2018

(30) Foreign Application Priority Data
Aug. 26, 2015 (JP) 2015-166710

(51) Int. Cl. C09K 5/14; C08K 3/38; C08K 7/18; H05K 7/20

(52) U.S. Cl. CPC C09K 5/14; C08K 3/38; C08K 7/18; C08K 2201/005; C08K 2003/385; C08K 2201/001; H05K 7/2039

(57) ABSTRACT

A heat dissipation member having excellent thermal conductivity and dielectric breakdown characteristics is able to be achieved by using a thermally conductive resin composition according to the present invention. A thermally conductive resin composition which is characterized in that: the blending ratio of a spherical boron nitride fine powder having an average particle diameter of 0.05-1.0 μm, an average circularity of 0.80 or more and a purity of boron nitride of 96% by mass or more to a boron nitride coarse powder having an average particle diameter of 20-85 μm and a graphitization index of 1.5-4.0 is from 5:95 to 40:60 in terms of volume ratio; and the total content of the spherical boron nitride fine powder and the boron nitride coarse powder in the resin composition is 40-85% by volume. A heat dissipation sheet which uses this thermally conductive resin composition. A heat dissipation member for electronic components, which uses this thermally conductive resin composition.

### TECHNICAL FIELD

The present invention relates to a thermally conductive resin composition.

### BACKGROUND ART

Heat-generating electronic components such as transistors, thyristors, CPUs are facing an important task of efficient heat dissipation during their use. In recent years, higher-integration of circuits in electronic components, which increases the amount of heat generation, needs a heat dissipation sheet having higher thermal conductivity than conventional one. In addition, since insulation reliability is also an import property, a heat dissipation sheet having higher insulation is demanded.

A heat dissipating filler used in the electronic components often uses coarse powder of several μm to several tens μm and fine powder of submicron(s) to several μm together, and the fine powder plays an important role in reducing the interface heat resistance.

Particularly, the fine powder applied to the heat dissipating sheet is preferably spherical in the powder form, and originally spherical alumina fine powder has been mainly applied. However, there is no case that spherical boron nitride fine powder is used as the heat dissipating filler.

In recent years, the high performance of computers and electronic devices further stresses an importance of heat dissipation measures. In such situation, hexagonal boron nitride (hereinafter referred to as “boron nitride”) has been focused on the filler having higher thermal conductivity and insulating property.

However, boron nitride is generally a specific flake shape, and in its thermal property, a-axis direction is overwhelmingly superior to the c-axis direction. Therefore, for example, a thermal property of a composite material filled with boron nitride in a resin such as silicone is affected by the orientation of boron nitride particles in the composite material.

For example, when the composite material is produced in the form of a sheet, the c-axis direction of the boron nitride particles tends to be orientated to a thickness direction of the sheet, resulting in that a sufficient thermal property required in the thickness direction cannot be obtained. Furthermore, when the flake-shape boron nitride fine powder is added to a resin, the viscosity of the resin extremely increases, resulting in a poor fillability.

Therefore, for the purpose that the boron nitride is suitable as higher thermal conductive filler, the boron nitride is required to be a spherical shape or agglomerate shape for the small influence of grain orientation and improvement of fillability.

Patent Document 1 discloses a method for producing a heat dissipating member, and Patent Documents 2 and 3 disclose a heat dissipating composition used in a circuit board, the composition comprising hexagonal boron nitride with higher thermal conductivity and lower dielectric constant is kneaded and dispersed in a resin.

Patent Document 4 proposes that boron nitride is generally obtained by reacting a boron source (boric acid, borax, etc.) with a nitrogen source (urea, melamine, ammonia, etc.) at high temperature, and is formed in the “pine cones” in which scaly primary particles generated from boric acid and melamine are aggregated. However, the aggregated particle size of boron nitride produced by this method is 50 μm or more, and it is difficult to prepare the spherical boron nitride fine powder used in the present invention.

On the other hand, it is reported that a method for producing spherical boron nitride fine powder by gas phase synthesis method (Patent Document 5, and Patent Document 6). However, such spherical boron nitride fine powder has never been applied to a thermal conductive filler before. In addition, since the conventional spherical boron nitride fine powder produced by these methods has a lower purity, higher thermal conductivity, which is characteristic of boron nitride, can not be obtained.

Furthermore, it is reported that a uniform dispersion of fine insulating fillers such as silicates improves dielectric breakdown strength (Patent Document 7, and Non-Patent Document 1). But, there is no example that spherical boron nitride fine powder is used as an insulating filler.

It is reported that a mixture of boron nitride powder coarse powder and fine powder are used, but there is no example that spherical boron nitride fine powder is not used (Patent Document 8).

### CITATION LIST

### Patent Literature

Patent Document 1: Japanese Patent Application Laid-open Publication No. 2009-094110A
Patent Document 2: Japanese Patent Application Laid-open Publication No. 2008-280436A
Patent Document 3: Japanese Patent Application Laid-open Publication No. 2008-050526A
Patent Document 4: Japanese Patent Application Laid-open Publication No. H09-202663A
Patent Document 5: Japanese Patent Application Laid-open Publication No. 2000-327312A
Patent Document 6: Japanese Patent Application Laid-open Publication No. 2004-182572A
Patent Document 7: Japanese Patent Application Laid-open Publication No. 2005-251543A
Patent Document 8: Japanese Patent Application Laid-open Publication No. 2005-343728A

### Non-Patent Literature

Non-Patent Document 1: IEEE Transactions on Dielectrics and Electrical Insulation Vol. 13, No. 1; February 2006

### SUMMARY OF INVENTION

### Technical Problem

The present invention provides a thermally conductive resin composition having good thermal conductivity and dielectric breakdown property. In particular, the present invention provides a thermally conductive resin composition having good thermal conductivity and dielectric breakdown property, even when a thermal dissipating sheet has a thickness of 1 mm as a thermal dissipation member for electronic components.

### Solution to Problem

The present invention adopts the following means in order to solve the above-mentioned problem.

(1) A thermally conductive resin composition comprising spherical boron nitride fine powder and boron nitride coarse powder, the spherical boron nitride fine powder having an average particle size of 0.05 to 1.0 μm, an average circularity of 0.80 or more, and a boron nitride purity of 96% by mass or more, the boron nitride coarse powder having an average particle size of 20 to 85 μm and a graphitization index of 1.5 to 4.0, wherein the blending ratio of the spherical boron nitride fine powder and the boron nitride coarse powder is 5:95 to 40:60 by volume ratio, and the total content of the spherical boron nitride fine powder and the boron nitride coarse powder in the thermally conductive resin composition is 40 to 85% by volume.

(2) A heat dissipation sheet comprising the thermally conductive resin composition according to (1).

(3) A heat dissipation member for electronic components comprising the thermally conductive resin composition according to (1).

### Advantageous Effects of Invention

The thermally conductive resin composition according to the present invention can provide a heat dissipation member having good thermal conductivity and dielectric breakdown property.

### DESCRIPTION OF EMBODIMENTS

The present invention provides a thermally conductive resin composition comprising spherical boron nitride fine powder and boron nitride coarse powder, the spherical boron nitride fine powder having the average particle size of 0.05 to 1.0 μm, the average circularity of 0.80 or more, and a boron nitride purity of 96% by mass or more, the boron nitride coarse powder having the average particle size of 20 to 85 μm and a graphitization index of 1.5 to 4.0, wherein the blending ratio of the spherical boron nitride fine powder and the boron nitride coarse powder is 5:95 to 40:60 by volume ratio, and the total content of the spherical boron nitride fine powder and the boron nitride coarse powder in the thermally conductive resin composition is 40 to 85% by volume.

The spherical boron nitride fine powder according to the present invention is produced not by a solid phase method which is a conventional method for producing hexagonal boron nitride, but by a so-called gas phase synthesis method using volatilized alkoxide borate and ammonia as a raw material in an inert gas flow within a tubular furnace (firing condition 1), then firing in a resistance heating furnace (firing condition 2), and finally charging this fired product in a boron nitride crucible and firing it in an induction heating furnace to produce boron nitride fine powder (firing condition 3). In firing condition 3, firing is preferably performed at 1,800 to 2,200° C. under a nitrogen atmosphere, for achieving higher purity and higher crystallinity required for the present invention.

It should be noted that the spherical boron nitride fine powder according to the present invention is not produced by pulverizing or otherwise reducing a conventional hexagonal boron nitride powder.

The spherical boron nitride fine powder used in the present invention has the average particle size of 0.05 to 1.0 μm. If it is less than 0.05 μm, a viscosity increases greatly in a mixture with the resin, and thereby the blending amount of the spherical boron nitride fine powder can not be increased, resulting in that the dielectric breakdown property can not to be improved. If it exceeds 1.0 μm, the dielectric breakdown property can not to be improved.

The average circularity of the spherical boron nitride fine powder used in the present invention is 0.80 or more for an improvement of the fillability and a smaller influence of orientation. It may be preferably 0.90 or more.

The boron nitride purity of the spherical boron nitride fine powder used in the present invention is 96% by mass or more from the viewpoint of obtaining higher thermal conductivity and good dielectric breakdown property. If it is less than 96% by mass, crystallinity may be poor and the amount of impurities may be larger, resulting in poor thermal conductivity and dielectric breakdown property, which is unpreferrable.

The orientation index of the spherical boron nitride fine powder used in the present invention is represented by the ratio (I₀₀₂/I₁₀₀) of the diffraction intensity I₀₀₂ on the (002) plane to the diffraction intensity I₁₀₀ on the (100) plane measured by the powder X-ray diffraction method, and it may be preferably 15 or less from the viewpoint of obtaining higher thermal conductivity.

The boron nitride coarse powder used in the present invention is primary particles of hexagonal boron nitride or secondary particles in which the primary particles are aggregated. The secondary particles may preferably have a nearly spherical shape from the viewpoint of thermal conductivity.

The boron nitride coarse powder used in the present invention has the average particle size of 20 to 85 μm and the graphitization index of 1.5 to 4.0.

If the average particle size is less than 20 μm, contact points between the boron nitride composite coarse particles increase, resulting in a poor thermal conductivity. If the average particle size exceeds 85 μm, the particle strength of the boron nitride composite powder decreases, then the spherical structure would be destroyed by the shearing stress received during kneading with the resin, resulting in that the primary particles of the hexagonal boron nitride particles are oriented in the same direction or the viscosity increases, which is unpreferrable.

If the graphitization index is larger than 4.0, the higher thermal conductivity may not be obtained due to lower crystallinity of the hexagonal boron nitride particles. If the graphitization index is smaller than 1.5, the hexagonal boron nitride particles develops in the form of flake, and may not maintain the aggregated structure in the form of aggregated particles, resulting in a lower thermal conductivity, which is unpreferrable.

The total content of the spherical boron nitride fine powder and the boron nitride coarse powder as the thermally conductive filler in the resin composition is 40 to 85% by volume. It may be more preferably 60 to 80% by volume. If the content of the thermally conductive filler is less than 40% by volume, the thermal conductivity of the resin composition may be lower. If the content exceeds 85% by volume, the resin composition is likely to have voids, resulting in a lower dielectric breakdown property and poor mechanical strength, which is unpreferrable.

Use of the spherical boron nitride fine powder and the boron nitride coarse powder together allows a higher filling rate of the whole thermally conductive filler by filling the fine powder particles between the coarse powder particles. For the blending ratio of the spherical boron nitride fine powder and the boron nitride coarse powder in the thermally conductive filler, the volume ratio of the spherical boron nitride fine powder to the boron nitride coarse powder is from 5:95 to 40:60, and may be preferably 5:95 to 30:70. If the blending ratio of the spherical boron nitride fine powder is higher, the fluidity of the resin composition is lower, and more voids tend to be formed in the resin composition, resulting in a lower dielectric breakdown property and poor mechanical strength, which is unpreferrable.

The resin used in the present invention may include silicone resins, acrylic resins, and epoxy resins. Though millable silicones are representative as silicone resins, the millable silicones are often difficult to generally exhibit a flexibility to be required. Therefore, an addition reaction type silicone is more suitable for realizing higher flexibility. An organopolysiloxane may be used as the silicon resin, and may be linear or branched as long as it has at least two alkenyl groups directly bonded to a silicon atom in one molecule. The organopolysiloxane may be used alone or in combination with one another having different viscosity. The alkenyl group may include vinyl group, allyl group, 1-butenyl group, and 1-hexenyl group, and generally the vinyl group may be preferably used from the viewpoint of easy synthesis and cost. The other organic group bonded to the silicon atom may include alkyl group such as methyl group, ethyl group, propyl group, butyl group, hexyl group, and dodecyl group; aryl group such as phenyl group; aralkyl group such as 2-phenylethyl group and 2-phenylpropyl group, and furthermore chloromethyl group, and substituted hydrocarbon group such as 3,3,3-trifluoropropyl group. Among of them, the methyl group may be preferably used.

Thermal conductivity of the heat dissipation sheet are calculated by multiplying thermal diffusivity, density, and specific heat of the resin composition according to ASTM E-1461 (Thermal conductivity=thermal diffusivity×density×specific heat). The thermal diffusivity is determined by laser flash method with samples processed to have a width 10 mm×length 10 mm×thickness 1 mm. As the measuring apparatus, a xenon flash analyzer (“LFA 447 NanoFlash” available from NETZSCH) is used to measure the thermal conductivity at 25° C. The density is determined using the Archimedes method. The specific heat is measured using DSC (“ThermoPlus Evo DSC 8230” available from Rigaku Corporation).

Dielectric breakdown voltages of the heat dissipation sheet are measured with prepared samples having the size of 100 mm×100 mm using a dielectric breakdown test apparatus (available from Yamayo Shikenki Co., Ltd.) according to JIS C 2110. The test is performed by a short time method, and the electrodes of a 25 mm φ cylinder/75 mm φ cylinder are used. In insulating oil, voltages are applied to the thermal conductive resin sheets held between heat dissipation members at increased rate so that dielectric breakdown occurs between 10 and 20 seconds after voltage application to measure the dielectric breakdown voltage, and which is divided by the thickness of the conductive resin sheet. The dielectric breakdown voltages are measured at 5 or more points and the average value is recorded.

<Measuring Method>

The spherical boron nitride powder used in the present invention is analyzed by the following measuring method.

(1) Average particle size: The average particle size is measured using a laser diffraction scattering particle size distribution measuring apparatus (“LS-13 320” available from Beckman Coulter, Inc.). The average particle size obtained is based on the volume statistical value.

(2) Orientation index: an X-ray diffractometer (“Geiger Flex 2013” model available from Rigaku Corporation” is used in the range of 2θ=25° to 45° to measure the intensity I₀₀₂ of a diffraction line in the vicinity of 2θ=27° to 28° (the (002) plane) and the intensity I₁₀₀ of a diffraction line in the vicinity of 2θ=41° (the (100) plane). The orientation index I₀₀₂/I₁₀₀ is figured out based on the peak intensity ratio of X-ray diffraction of boron nitride.

(3) Boron nitride purity: The boron nitride purity is measured by the following method: a sample is subjected to decomposition with an alkali sodium hydroxide, and ammonia is distilled out by a steam distillation process for collection in a boric acid solution. The resultant solution is titrated with a sulfuric acid normal solution to determine the amount of nitrogen (N), after which the boron nitride purity (BN) is calculated based on the following formula:

BN (% by mass)=N (% by mass)×1.772.

(4) Average circularity: A particle image is taken using a scanning electron microscope (SEM) or a transmission electron microscope (TEM), and then is analyzed using an image analyzer (for example, “MacView”, available from Mountech Co., Ltd.) to measure a projection area (S) and peripheral length (L) of the particle. The circularity is found by:

Average circularity: circularity=4πS/L².

One hundred particles are arbitrarily selected to measure their circularity respectively and the average value thereof is regarded as the average circularity of the sample. The microscopic pictures are analyzed in the manual recognition mode at 10,000 times to 100,000 times, image resolution 1280×1024 pixels. The minimum particle size to be measured is 20 nm.

(5) Graphitization Index: The graphitization index can be determined based on the integrated intensity ratio of the peaks, that is the area ratio of the (100), (101) and (102) planes of the X-ray diffraction diagram, by the following formula: GI=[area {(100)+(101)}]/[area (102)]. See J. Thomas, et. al, J. Am. Chem. Soc., 84, 4619 (1962). It is noted that GI of fully crystallized boron nitride is 1.60, but that of the flake-shape hexagonal boron nitride powder having high crystallinity with sufficiently grown particles becomes more smaller since the particles tend to be oriented in the same direction. That is, GI is an index of the crystallinity of the flake-shape hexagonal boron nitride powder, and the smaller the value, the higher the crystallinity.

### EXAMPLES

Hereinafter, the present invention will be described in detail by examples and comparative examples.

The spherical boron nitride fine powder of Example 1 was synthesized as follows.

(Firing Condition 1)

A furnace core tube was placed in a resistance heating furnace and heated to 1000° C. Trimethyl borate (“TMB-R” available from Tama Chemicals Co., Ltd.) was introduced into the furnace core tube through an inlet pipe by nitrogen bubbling, while ammonia gas (purity of 99.9% or more) was also introduced into the furnace core tube through the inlet pipe. The introduced trimethyl borate and ammonia were subjected to gas phase synthesis in the furnace at the molar ratio of 1:1.2 at a reaction time of 10 seconds to yield a white powder product. The resultant white powder product was recovered.

(Firing Condition 2)

The white powder recovered under firing condition 1 was charged in a boron nitride crucible, placed in the resistance heating furnace, and heated and fired at a temperature of 1350° C. under a mixed atmosphere of nitrogen and ammonia for 5 hours. After completion of the firing, the fired product was cooled down to be recovered.

(Firing Condition 3)

The fired products obtained under the firing condition 2 was placed in a boron nitride crucible and fired at 2000° C. for 4 hours under a nitrogen atmosphere in an induction heating furnace to obtain a boron nitride fine powder.

The hexagonal boron nitride coarse powder was synthesized as follows.

16 wt % of an amorphous boron nitride powder (the oxygen content of 2.5%, BN purity of 96% and average particle size of 4 μm), 5 wt % of a hexagonal boron nitride powder (the oxygen content of 0.1%, BN purity of 99% and average particle size of 13 μm), 0.5 wt % of a calcium carbonate (“PC-700” available from Shiraishi Kogyo Kaisha, Ltd.), and 78.5 wt % water were mixed using a Henschel mixer and then pulverized with a ball mill to yield an aqueous slurry. Subsequently, 0.5 part by mass of a polyvinyl alcohol resin (“Gohsenol” available from Nippon Synthetic Chemical Industry Co., Ltd.) was added to 100 parts by mass of the aqueous slurry, and the mixture was heated and stirred at 50° C. until dissolved, and then spheroidized at a drying temperature of 230° C. in a spray drier. As a spheroidizer for the spray dryer, a rotary atomizer was used at 8000 rpm. The obtained treated product was fired at 1850° C. in a batch type high frequency furnace and then the fired product was crushed and classified to yield a boron nitride coarse powder.

The spherical boron nitride fine powder, hexagonal boron nitride coarse powder, and addition reaction type liquid silicone resin (“SE-1885 A/B” available from Dow Corning Toray Co., Ltd.) were mixed at room temperature in the percentage (volume %) shown in Table 1, using a planetary centrifugal mixer (“THINKY MIXER” available from THINKY CORPORATION) at a rotation speed of 2000 rpm for 10 minutes to produce a resin composition.

### Example 2

In Example 2, except that the molar ratio of trimethyl borate and ammonia under the firing condition 1 for the spherical boron nitride fine powder was set to 1:9, the resin composition was produced in the same manner as in Example 1.

### Example 3

In Example 3, except that the heating temperature under the firing condition 1 for the spherical boron nitride fine powder was set to 800° C., the resin composition was produced in the same manner as in Example 1.

### Example 4

In Example 4, except that the rotation speed of the rotary atomizer for the hexagonal boron nitride coarse powder was set to 14000 rpm, the resin composition was produced in the same manner as in Example 1.

### Example 5

In Example 5, except that the rotation speed of the rotary atomizer for the hexagonal boron nitride coarse powder was set to 6500 rpm, the resin composition was produced in the same manner as in Example 1.

### Examples 6 to 9

In Examples 6 and 7, the blending ratio of the thermally conductive filler was changed, and in Examples 8 and 9, the blending ratio of the spherical boron nitride fine powder in the thermally conductive filler was changed to produce a resin composition.

### Example 10

In Example 10, except that the synthesis temperature under the firing condition 3 for the spherical boron nitride fine powder was set to 1750° C., the resin composition was produced in the same manner as in Example 1.

### Example 11

In Example 11, except that the molar ratio of trimethyl borate and ammonia under the firing condition 1 for the spherical boron nitride fine powder was set to 1:3.5, and the synthesis temperature under the firing condition 2 was set to 1050° C., the resin composition was produced in the same manner as in Example 1.

### Example 12

In Example 12, except that the firing temperature of the hexagonal boron nitride coarse powder was set to 2000° C., the resin composition was produced in the same manner as in Example 1.

### Example 13

In Example 13, except that the firing temperature of the hexagonal boron nitride coarse powder was set to 1750° C., the resin composition was produced in the same manner as in Example 1.

### Comparative Example 1

In Comparative Example 1, except that the spherical boron nitride fine powder was not used, the resin composition was produced in the same manner as in Example 1.

### Comparative Example 2

In Comparative Example 2, except that the molar ratio of trimethyl borate and ammonia under the firing condition 1 for the spherical boron nitride fine powder was set to 1:12, the resin composition was produced in the same manner as in Example 1.

### Comparative Example 3

In Comparative Example 3, except that the firing time under the firing condition 2 for the spherical boron nitride fine powder was set to 10 minutes, the resin composition was produced in the same manner as in Example 1.

### Comparative Example 4

In Comparative Example 4, except that the firing time under the firing condition 2 for the spherical boron nitride fine powder was set to 2 hours and the firing condition 3 was not performed, the resin composition was produced in the same manner as in Example 1.

Comparative Examples 5, 6 and 10 In Comparative Examples 5, 6 and 10, the blending ratio of the spherical boron nitride fine powder in the thermally conductive filler was changed to produce a resin composition.

### Comparative Example 7

In Comparative Example 7, except that the reaction time under the firing condition 1 for the spherical boron nitride fine powder was set to 40 seconds, the resin composition was produced in the same manner as in Example 1.

### Comparative Example 8

In Comparative Example 8, except that the firing temperature of the hexagonal boron nitride coarse powder was set to 2100° C., the resin composition was produced in the same manner as in Example 1.

### Comparative Example 9

In Comparative Example 9, except that the firing temperature of the hexagonal boron nitride coarse powder was set to 1650° C., the resin composition was produced in the same manner as in Example 1.

### Comparative Examples 11 and 12

In Comparative Examples 11 and 12, the blending ratio of the spherical boron nitride fine powder in the thermally conductive filler was changed to produce a resin composition.

### Comparative Example 13

In Comparative Example 13, except that the rotation speed of the rotary atomizer for the hexagonal boron nitride coarse powder was set to 17000 rpm, the resin composition was produced in the same manner as in Example 1.

### Comparative Example 14

In Comparative Example 14, except that the rotation speed of the rotary atomizer for the hexagonal boron nitride coarse powder was set to 4200 rpm, the resin composition was produced in the same manner as in Example 1.

100 g of the resin composition was filled in a cylinder structure mold fixed with a die having a slit (1 mm×100 mm) and extruded through the slit at a pressure of 5 MPa with a piston to prepare a resin composition sheet. This sheet was heated at 110° C. for 3 hours for evaluating thermal conductivity and dielectric breakdown property. The thickness of the evaluated sheet was 1.0 mm.

Results of the measured thermal conductivity and the dielectric breakdown voltage of the resin composition sheet obtained as above are shown in Tables 1 to 4. It is noted that when it was difficult to prepare a sheet due to poor fluidity of the resin composition after mixing, it is determined that it could not be prepared.

For the evaluation of the thermal conductivity and dielectric breakdown voltage according to the present invention, when the heat dissipation sheet having a thickness of 1 mm has a thermal conductivity of 8 W/(m·K) or more and a dielectric breakdown voltage of 20 kV/mm or more, it is regarded as having a good thermal conductivity and good dielectric breakdown property.

TABLE 1

| Category | Evaluation Subject | | Example 1 | Example 2 | Example 3 | Example 4 | Example 5 | Example 6 | Example 7 | Example 8 |
|---|---|---|---|---|---|---|---|---|---|---|
| Materials | spherical BN fine | average particle | 0.5 | 0.1 | 0.9 | 0.5 | 0.5 | 0.5 | 0.5 | 0.5 |
| | powder | size μm | | | | | | | | |
| | | average circularity | 0.9 | 0.9 | 0.9 | 0.9 | 0.9 | 0.9 | 0.9 | 0.9 |
| | | orientation index | 8 | 7 | 6 | 8 | 8 | 8 | 8 | 8 |
| | | purity % | 99 | 99 | 99 | 99 | 99 | 99 | 99 | 99 |
| | BN coarse powder | average particle | 45 | 45 | 45 | 20 | 80 | 45 | 45 | 45 |
| | | size μm | | | | | | | | |
| | | graphitization | 2.6 | 2.6 | 2.6 | 2.8 | 2.6 | 2.6 | 2.6 | 2.6 |
| | | index | | | | | | | | |
| Blending | blending ratio of BN | volume % | 15 | 15 | 15 | 15 | 15 | 15 | 15 | 5 |
| | fine powder in filler | | | | | | | | | |
| | content of filler | volume % | 60 | 60 | 60 | 60 | 60 | 45 | 80 | 60 |
| | content of resin | volume % | 40 | 40 | 40 | 40 | 40 | 55 | 20 | 40 |
| Evaluated | thermal conductivity | W/(m · K) | 10 | 9 | 10 | 9 | 11 | 9 | 12 | 9 |
| Physical | dielectric breakdown | kV/mm | 22 | 23 | 21 | 22 | 21 | 22 | 22 | 21 |
| Property | voltage | | | | | | | | | |

TABLE 2

| Category | Evaluation Subject | | Example 9 | Example 10 | Example 11 | Example 12 | Example 13 |
|---|---|---|---|---|---|---|---|
| Materials | spherical BN fine | average particle | 0.5 | 0.5 | 0.5 | 0.5 | 0.5 |
| | powder | size μm | | | | | |
| | | average circularity | 0.9 | 0.9 | 0.9 | 0.9 | 0.9 |
| | | orientation index | 8 | 8 | 11 | 8 | 8 |
| | | purity % | 99 | 96 | 99 | 99 | 99 |
| | BN coarse powder | average particle | 45 | 45 | 45 | 45 | 45 |
| | | size μm | | | | | |
| | | graphitization | 2.6 | 2.6 | 2.6 | 1.5 | 4.0 |
| | | index | | | | | |
| Blending | blending ratio of BN | volume % | 35 | 15 | 15 | 15 | 15 |
| | fine powder in filler | | | | | | |
| | content of filler | volume % | 60 | 60 | 60 | 60 | 60 |
| | content of resin | volume % | 40 | 40 | 40 | 40 | 40 |
| Evaluated | thermal conductivity | W/(m · K) | 8 | 10 | 9 | 9 | 9 |
| Physical | dielectric breakdown | kV/mm | 24 | 22 | 22 | 22 | 21 |
| Property | voltage | | | | | | |

TABLE 3

| | | | Comparative | Comparative | Comparative | Comparative |
|---|---|---|---|---|---|---|
| Category | Evaluation Subject | | Example 1 | Example 2 | Example 3 | Example 4 |
| Materials | spherical BN fine | average particle | — | 0.04 | 0.2 | 0.5 |
| | powder | size μm | | | | |
| | | average circularity | — | 0.9 | 0.4 | 0.9 |
| | | | | | (flake- | |
| | | | | | shape) | |
| | | orientation index | — | 7 | 25 | 8 |
| | | purity % | — | 99 | 99 | 90 |
| | BN coarse powder | average particle | 45 | 45 | 45 | 45 |
| | | size μm | | | | |
| | | graphitization | 2.6 | 2.6 | 2.6 | 2.6 |
| | | index | | | | |
| Blending | blending ratio of BN | volume % | 0 | 15 | 15 | 15 |
| | fine powder in filler | | | | | |
| | content of filler | volume % | 60 | 60 | 60 | 60 |
| | content of resin | volume % | 40 | 40 | 40 | 40 |
| Evaluated | thermal conductivity | W/(m · K) | 7 | can not be | can not be | 7 |
| Physical | | | | prepared | prepared | |
| Property | dielectric breakdown | kV/mm | 18 | — | — | 17 |
| | voltage | | | | | |
| | | | Comparative | Comparative | Comparative | Comparative |
| Category | Evaluation Subject | | Example 5 | Example 6 | Example 7 | Example 8 |
| Materials | spherical BN fine | average particle | 0.5 | 0.5 | 1.5 | 0.5 |
| | powder | size μm | | | | |
| | | average circularity | 0.9 | 0.9 | 0.9 | 0.9 |
| | | orientation index | 8 | 8 | 8 | 8 |
| | | purity % | 99 | 99 | 99 | 99 |
| | BN coarse powder | average particle | 45 | 45 | 45 | 45 |
| | | size μm | | | | |
| | | graphitization | 2.6 | 2.6 | 2.6 | 1.0 |
| | | index | | | | |
| Blending | blending ratio of BN | volume % | 2 | 60 | 15 | 15 |
| | fine powder in filler | | | | | |
| | content of filler | volume % | 60 | 60 | 60 | 60 |
| | content of resin | volume % | 40 | 40 | 40 | 40 |
| Evaluated | thermal conductivity | W/(m · K) | 7 | can not be | 9 | 6 |
| Physical | | | | prepared | | |
| Property | dielectric breakdown | kV/mm | 18 | — | 18 | 20 |
| | voltage | | | | | |

TABLE 4

| | | | Comparative | Comparative | Comparative | Comparative | Comparative | Comparative |
|---|---|---|---|---|---|---|---|---|
| Category | Evaluation Subject | | Example 9 | Example 10 | Example 11 | Example 12 | Example 13 | Example 14 |
| Materials | spherical BN fine | average particle | 0.5 | 0.5 | 05 | 0.5 | 0.5 | 0.5 |
| | powder | size μm | | | | | | |
| | | average circularity | 0.9 | 0.9 | 0.9 | 0.9 | 0.9 | 0.9 |
| | | orientation index | 8 | 8 | 8 | 8 | 8 | 8 |
| | | purity % | 99 | 99 | 99 | 99 | 99 | 99 |
| | BN coarse powder | average particle | 45 | 45 | 45 | 45 | 10 | 110 |
| | | size μm | | | | | | |
| | | graphitization | 5.5 | 2.6 | 2.6 | 2.6 | 2.6 | 2.6 |
| | | index | | | | | | |
| Blending | blending ratio of BN | volume % | 15 | 50 | 15 | 15 | 15 | 15 |
| | fine powder in filler | | | | | | | |
| | content of filler | volume % | 60 | 60 | 35 | 90 | 60 | 60 |
| | content of resin | volume % | 40 | 40 | 65 | 10 | 40 | 40 |
| Evaluated | thermal conductivity | W/(m · K) | 5 | 6 | 4 | can not be | 5 | can not be |
| Physical | | | | | | prepared | | prepared |
| Property | dielectric breakdown | kV/mm | 20 | 23 | 15 | — | 20 | — |
| | voltage | | | | | | | |

The comparison between the Examples and the Comparative Example on Tables 1 to 4 apparently shows that the thermally conductive resin composition according to the present invention has good thermal conductivity and high dielectric breakdown voltage, even when it has the thickness of 1 mm.

### INDUSTRIAL APPLICABILITY

The thermally conductive resin composition according to the present invention can be widely used for a heat dissipation member.

1. A thermally conductive resin composition comprising spherical boron nitride fine powder and boron nitride coarse powder, the spherical boron nitride fine powder having an average particle size of 0.05 to 1.0 μm, an average circularity of 0.80 or more, and a boron nitride purity of 96% by mass or more, the boron nitride coarse powder having an average particle size of 20 to 85 μm and a graphitization index of 1.5 to 4.0, wherein blending ratio of the spherical boron nitride fine powder and the boron nitride coarse powder is 5:95 to 40:60 by volume ratio, and a total content of the spherical boron nitride fine powder and the boron nitride coarse powder in the thermally conductive resin composition is 40 to 85% by volume.

2. A heat dissipation sheet comprising the thermally conductive resin composition according to claim 1.

3. A heat dissipation member for electronic components comprising the thermally conductive resin composition according to claim 1.
